(19) United States
(12) Patent Application Publication
(10) Pub. No.: US 2009/0194165 A1
(43) Pub. Date: Aug. 6, 2009

(54) Ultra-high current density cadmium telluride photovoltaic modules

(75) Inventors: Brian Murphy, Golden, CO (US); Russell Black, Longmont, CO (US); Ken Zweibel, Golden, CO (US); Fred Seymour, Evergreen, CO (US); Mark Auble, Longmont, CO (US); Jack Little, Denver, CO (US)

Correspondence Address: YOUNG & THOMPSON, 209 Madison Street, Suite 500, ALEXANDRIA, VA, 22314, US

(73) Assignee: PRIMESTAR SOLAR, INC., GOLDEN, CO (US)

(21) Appl. No.: 12/010,919

(22) Filed: Jan. 31, 2008

(51) Int. Cl. H01L 31/0296; H01L 31/04; H01L 31/0216; C23C 14/34; H01L 31/18

(52) U.S. Cl. 136/260; 136/265; 204/192.26

(57) ABSTRACT

Solar photovoltaic (PV) modules have the highest possible conversion of photons to electrons in order to optimize their sunlight-to-electricity energy conversion efficiency. The electric current and sunlight-to-electricity conversion efficiency of CdTe modules is increased by about 20% with a new module design that (1) allows more light to pass through the glass and top layers to reach the PV junction area while (2) protecting the module against manufacturability pitfalls (shorts, shunts, and weak diodes) that have previously prevented the successful development of any equivalent module.

### BACKGROUND OF THE INVENTION

1. Field of the Invention

The invention relates to a high-performance cadmium telluride PV module, with significant efficiency enhancement and cost reduction.

2. Description of the Related Art

Thin film solar modules based on cadmium telluride (CdTe) and copper indium diselenide (CIS) are among the most successful in photovoltaics (PV) in terms of their cost at the module and system levels. Production volumes of CdTe solar modules (made using large areas of CdTe solar cells deposited on glass) have grown rapidly to about 200 MW annually, with construction underway for a gigawatt production. Systems installed using CdTe PV modules are reportedly the lowest cost PV systems of any kind, with ground-mounted systems at about $4/Wp and commercial rooftop systems at about $5/W, both about 20% lower than any other PV module technology. Thus thin film PV technology is important for the future of harnessing sunlight for terrestrial energy.

Related art CdTe solar modules have reached 10% sunlight-to-electricity conversion efficiency. However, these modules fail to convert a significant portion of the solar spectrum above the band gap of one of the constituent films, cadmium sulfide (CdS), at 2.5 eV. These related art PV modules thus produce a maximum of about 20 mA/cm² active-area short circuit current density. A module's active area is defined as the surface area above the exposed CdS/CdTe junction, which is calculated by subtracting from the total module area the area of cell interconnects, grids (if any), the module edge delete and any protruding frame or appurtenance.

The theoretical maximum active-area current density for a CdTe solar cell is between 28 and 32 mA/cm². The variation depends on the band gap in the sensitive CdS/CdTe interface area. Intermixing CdS with CdTe can result in a band gap between 1.4 and 1.5 eV, causing the range of theoretical short-circuit current values.

There are two major losses of current that result in CdTe current densities close to 20 mA/cm² instead of 30 mA/cm². They are (1) absorption in the top glass, and (2) absorption in the top semiconductor layers that are over the CdTe. Approximately 10 mA/cm² are lost in these undesirable absorptions and reflections.

Related art thin film PV modules utilize window glass purchased from large, commercial glass makers. The window glass has various impurities. in it, and one that is purposely added is iron. A small amount of iron in the glass allows it to absorb more energy during glass making, allowing it to heat up faster during glass formation. But this also results in a visually imperceptible loss in light transmission in the final product—about 5%. Window glass absorbs in the iron impurities, which looks slightly green to the human eye.

Another typical loss in related art PV modules comes from the first few coatings that are put directly on the glass. Glass makers supply various coatings, but these were originally developed for non-PV uses (e.g., blocking UV light in skyscrapers) to control indoor temperatures, reflecting or trapping parts of the solar spectrum. These same coatings, usually made from tin oxide, are adaptable to CdTe PV modules, but are far from optimal. The tin oxide layer is conductive and transparent, and in PV use it is called a TCO, or transparent conductive oxide.

As a result, there is a need for new PV module technologies that minimize light loss and maximize current densities.

### SUMMARY OF THE INVENTION

An object of the invention, in part, is to provide a photovoltaic module that overcomes the disadvantages of the related art.

An object of the invention, in part, is to minimize the loss of solar photons in the glass and top layers of a PV module, thus maximizing the number of photons that can be effectively converted into electricity.

An object of the invention, in part, is to increase photon conversion in such a way that the overall sunlight-to-electricity energy conversion efficiency is substantially increased, so that the addition of increased photon conversion does not come at the expense of module voltage or fill factor.

The invention, in part, pertains to a photovoltaic module that may include a low-iron glass superstrate, a cadmium stannate conductive layer on the superstrate, a zinc tin oxide buffer layer on the conductive coating, and a cadmium sulfide layer having a thickness of about 0.1 μm or less on the buffer layer, where the photovoltaic module has an active-area current density of about 23 mA/cm² or more, preferably about 25 mA/cm² or more.

In the invention, the cadmium stannate conductive layer may be about 0.1-1 μm thick, the zinc tin oxide buffer layer may have a composition with a stoichiometric ratio of ZnO/SnO₂ between about 0.25 and 3, the zinc tin oxide buffer layer may have a thickness between about 0.01 and about 0.5 μm, and the cadmium sulfide layer may include oxygen up to 25% by atomic percent. The cadmium stannate layer, the zinc tin oxide layer, and the cadmium sulfide layer may be sputtered layers. The module will further include a photovoltaic semiconductor layer on the cadmium sulfide layer, and the photovoltaic layer is comprised of CdTe. The low iron glass may be low iron float glass containing less than about 0.15% by weight of Fe, and may have a transmissiveness of about 0.9 or greater in the spectrum of interest (about 300 to 900 nm wavelength). The cadmium stannate layer may have a thickness of about 0.3 μm. The module may have an area of about 120 cm×60 cm or larger.

The invention, in part, pertains to a method of manufacturing a photovoltaic module that may include providing a low-iron glass superstrate, sputtering a cadmium stannate conductive coating on the superstrate, sputtering a zinc tin oxide buffer layer on the conductive coating, and sputtering a cadmium sulfide having a thickness of about 1 μm or less on the buffer layer, wherein the photovoltaic module has an active-area current density of about 25 mA/cm² or more. The sputtering may be RF or DC magnetron sputtering at ambient temperature.

It is to be understood that both the foregoing general description and the following detailed description are exemplary and explanatory and are intended to provide further explanation of the invention as claimed.

### BRIEF DESCRIPTION OF THE DRAWING FIGURES

The accompanying drawings are included to provide a further understanding of the invention. The drawings illustrate embodiments of the invention and together with the description serve to explain the principles of the embodiments of the invention.

FIG. 1 is a schematic diagram of the layers in a module that lead to increased current density in a manufacturable module. Not all aspects of a PV module are shown.

FIG. 2 is a comparison of the transmission of low iron and normal window glass.

FIG. 3 shows the current versus voltage relationship of a high efficiency PV cell having an active-area current density greater than 25 mA/cm².

FIG. 4 is a quantum efficiency accounting of photon and current losses in a related art cell where commercial tin oxide on window glass is used.

FIG. 5 is a photon accounting for a CdTe cell made on highly transmissive glass and with advanced TCOs.

### DETAILED DESCRIPTION OF THE PREFERRED EMBODIMENTS

Advantages of the present invention will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

In the disclosure, when a layer is being described as “on” of “over” another layer or substrate, it is to be understood that the layer can either be directly in contact or that another layer or feature can intervene.

In general, the present invention utilizes a unique combination of glass, conductive transparent conductive oxide (TCO), buffer TCO, and thin CdS to achieve higher performance than related art modules by increasing the current density while maintaining other device parameters. In addition, the present invention achieves this in a way that provides an acceptable process window so that the device can be made in a large area at high throughput and high yield. Combined, these lead to higher efficiency and lower dollar per watt module cost, which then leads to significantly lower installed PV system costs.

A preferred embodiment of the invention is a thin film CdTe solar photovoltaic module. Such modules are used to produce solar electricity for numerous applications, for example, large ground-mounted systems and rooftop systems on commercial and residential buildings.

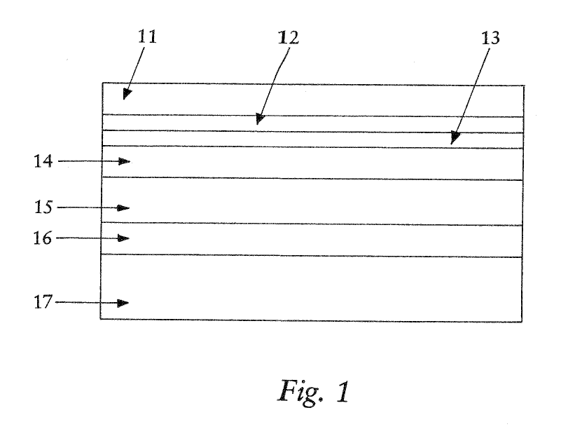

FIG. 1 is a diagram of a thin film photovoltaic module according to an embodiment of the invention.

In FIG. 1, a top sheet of high transmission glass 11 (called a superstrate, because it is the substrate on which the subsequent thin films are grown, but it faces upwards to the sun when in use in the final device) is employed as the substrate. The top sheet of glass or superstrate 11 can be a high-transmission, low-iron float glass. The top sheet of glass or superstrate 11 can also be a high transmission borosilicate glass.

The next layer 12 is a TCO, which allows light to pass through it with minimal absorption while also allowing electric current produced by the cell to travel sideways to opaque metal conductors (not shown). In a preferred embodiment, this TCO is about 0.3 pm of stoichiometric cadmium stannate (nominally Cd₂SnO₄).

The cadmium stannate layer can be formed by DC or RF sputtering a layer of substantially amorphous Cd₂SnO₄ onto the superstrate 11. Such sputtering can be performed from a hot-pressed target containing stoichiometric amounts of SnO₂ and CdO onto the superstrate 11 in a ratio of 1 to 2. The cadmium stannate can alternately be prepared using cadmium acetate and tin (II) chloride precursors by spray pyrolysis.

The subsequent layer 13 is a more resistive TCO buffer layer that protects the module from chemical interactions from the glass and those that might be incurred from subsequent processing. Without this buffer layer 13, losses at the cell level and module level would be compounded, making product manufacture of high-efficiency modules impractical.

In a preferred embodiment, the buffer TCO material is about 0.1 μm thick or less and is formed from a combination of ZnO and SnO₂ in about a one to two (1:2) stoichiometric ratio. This material and the prior layer 12 replace the related art tin oxide with other TCO layers that are not used for architectural applications and perform more optimally for PV.

The zinc tin oxide for the buffer layer 13 may be created by sputtering from a hot-pressed target containing stoichiometric amounts of about 67 mol % SnO₂ and about 33 mol % ZnO onto the TCO layer 12. As deposited by sputtering, the zinc tin oxide material may be substantially amorphous. The layer 13 may have a thicknesses of between about 200 and 3,000 Å, and preferably between about 800 and 1,500 Å, to have desirable mechanical, optical, and electrical properties. The film may have a wide optical bandgap (about 3.3 eV).

A thin CdS layer 14 (preferably from 0.01 to 0.1 μm thick) is next deposited. A typical CdS layer 14 may have a thickness of between about 500 and 800 Å. This layer 14 forms the junction with the PV semiconductor CdTe 15 to create the photovoltaic effect in the module, allowing it to generate electricity from sunlight.

In the CdTe modules of the related art, the CdS layer 14 is thicker and blocks most of the photons with energy above its 2.5 eV band gap, equivalent to about 4 mA/cm² of lost current density in the modules. The addition of the resistive buffer layer 13 permits the fabrication of CdS layers that are thinner than related art CdS layers, recapturing much of the lost light.

The CdS layer 14 may be formed by chemical bath deposition or by sputtering. The CdS layer 14 preferably has a smooth surface and is uniform and free of impurities and pinholes.

All the sputtering steps described above are preferably magnetron sputtering at ambient temperature under highly pure atmospheres. However, other deposition processes may be used, including higher temperature sputtering, electrodeposition, screen printing, physical vapor deposition (PVD), chemical vapor deposition (CVD) or spraying.

Light absorption depends on band gap and layer thickness, and it is always possible to make a layer thin enough to be semitransparent. But the consequences are that the layer usually becomes nonuniform and patchy, thus losing its functionality. But by adding the resistive ZTO buffer layer 13, the CdS layer 14 can be made thin enough to allow most of the photons to pass through it and still maintain a high quality junction.

Subsequently, layers of photovoltaic CdTe 15, a back contact 16, which may also be a combined set of processes and layers, and an encapsulating glass 17 are added to complete the module. Not shown are the barrier coating put directly on the glass superstrate before processing to prevent out-diffusion of impurities, the adherent layer for the back glass, buss bars, external wiring, and various conventional components, e.g., along the edge.

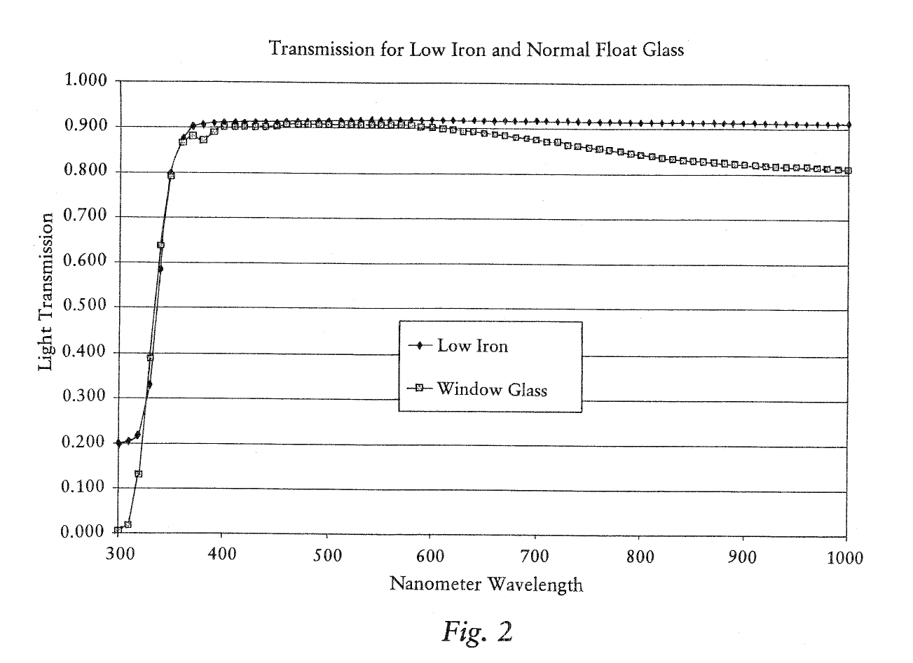

FIG. 2 shows the transmission of glass that absorbs less sunlight than conventional window glass. Such glass has less iron and is sometimes called “water white” glass for the increased transparency. Another more-transparent glass is borosilicate glass. Both of these have about 5% more transmission than window glass in the desired solar spectrum of CdTe absorption. The low iron glass has a transmission of about 0.900 or greater, preferably 0.910 or greater, from a wavelength range of about 300 nm to about 900 nm.

Low iron glass typically contains less than about 0.15% by weight of iron. The glass may contain between about 0.00001% and about 0.1% by weight of iron, more preferably less than 0.08% by weight, most preferably less than about 0.05% by weight.

Low iron glass can also be defined by iron oxide content. An iron oxide content of 0.1% by weight can yield a transmittance of 0.91.

For example, solar radiation absorption of related art 12 mm (½″) thick window glass is about 30%, while it is only 7% for 12 mm (½″) Pilkington OPTIWHITE™ low iron glass. Guardian ULTRAWHITE™ low iron glass has a transmission of about 91% at 3 mm (⅛″), 90% at 6 mm (¼″), and 89% at 12 mm (½″).

Related art window glass is inexpensive (about $4/m²) because it is made on a large-volume molten tin bath where sand is melted and floated to form the glass. This technology results in the least expensive glass. Borosilicate glass is about three times more expensive because it is not made on a float line. Low iron glass is a float glass, and except for the extra thermal energy needed during processing from not having iron in it, its cost is very similar to window glass. Thus it can be economically used in photovoltaic modules. However, it is also not known in the related art to coat tin oxide on low iron glass. Additionally, it is not known in the related art to utilize a superstrate that includes making a TCO pair to replace tin oxide.

The employment of high transmission glass such as low-iron iron float glass adds about 5% current density to CdTe cells, or about 1 mA/cm², as shown in the following wavelength-dependent transmission analysis of uncoated low-iron glass versus normal, higher-iron window glass.

The utilization of low iron glass allows the manufacture of large area modules of about 120 cm×60 cm or larger.

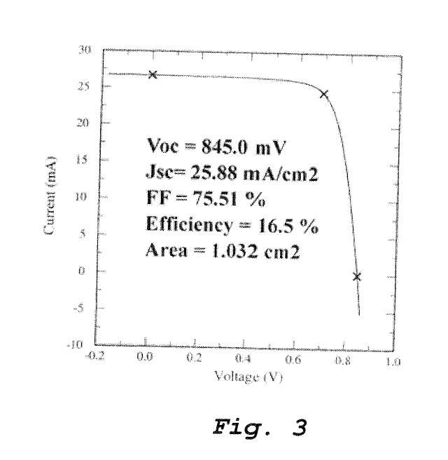

FIG. 3 shows the performance of a single thin film CdTe photovoltaic cell that utilizes a highly transmissive superstrate borosilicate glass. An active-area current Jsc over 25 MA/cm² may be observed at a voltage of 0.845 volts. An optimum current of about 26 mA/cm² may be observed.

In order to obtain active-area currents of 25 mA/cm² or greater, there are thus at least three factors to be considered:
1. Thinning the n-type CdS layer.
2. Adding a resistive buffer layer (ZTO) above the CdS to prevent a loss of voltage from thinning the CdS.
3. Replacing the related art tin oxide TCO with a higher quality TCO that transmits more light while conducting more current.

By adopting these approaches, the related art 16.5% efficiency small-area cell may be transformed into a large-area module to unexpectedly reach almost 26 mA/cm² in active-area current while maintaining a high voltage and fill factor. Increasing the current is an important improvement, but keeping the other parameters steady or improving them is also desirable. Some other approaches can increase the current but at the cost of lower voltage or fill factor and no aggregate increase in sunlight-to-electric conversion efficiency.

The advantages of the present invention are observable from a comparison of the greater than 25 mA/cm² obtainable when compared to related art CdTe modules that fail to capture light above the CdS band gap. Table 1 shows an analysis of two comparative CdTe modules. Both lack the additional current.

TABLE 1

| | | | | | | Active | Percent of |
|---|---|---|---|---|---|---|---|
| | | Active | | | | Area | Theoretical |
| | | Area | | | Cell | Current | Maximum (@ |
| | Size | (92%) | Current | Cells | Area | Density | 30 mA/cm²) |
| C1 | 7200 cm² | 6624 cm² | 1110 mA | 118 | 56.1 cm² | 19.8 mA/cm² | 66% |
| C2 | 7200 cm² | 6624 cm² | 1119 mA | 116 | 57.1 cm² | 19.6 mA/cm² | 65% |

Neither of these comparative modules C1 and C2 captures the light above the CdS band gap. In contrast, the present invention can yield an active area current of at least about 25 mA/cm², which is 83% of the theoretical maximum of about 30 mA/cm².

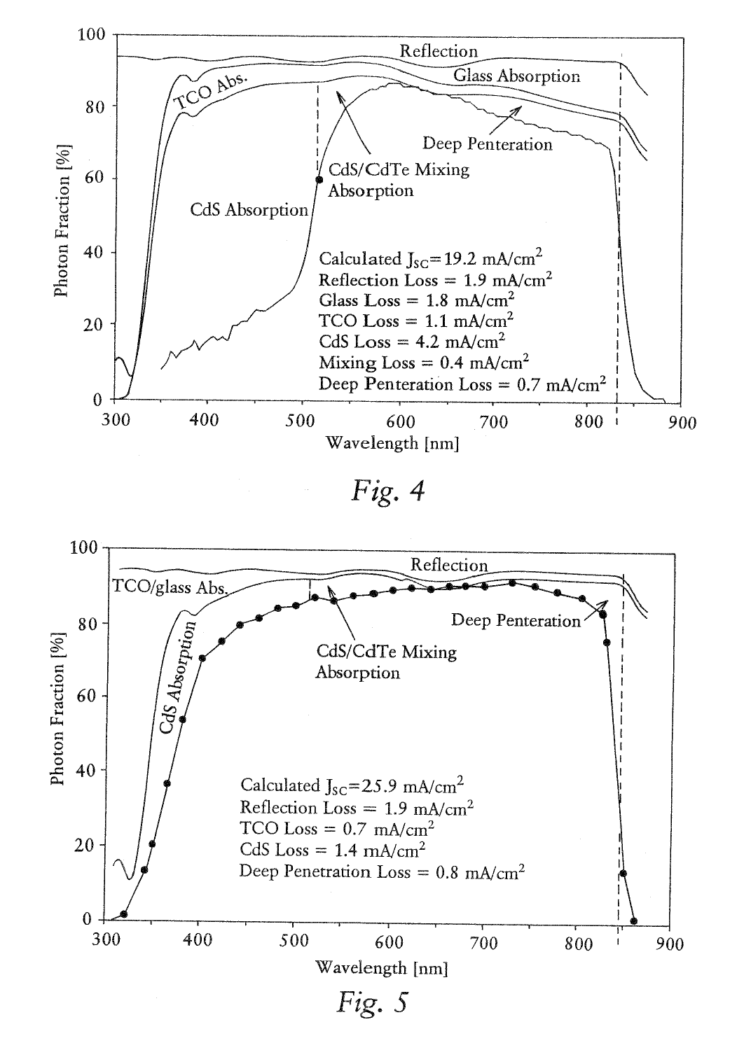

FIGS. 4 and 5 demonstrate a photon accounting of the related art compared to the present invention.

In FIGS. 4 and 5, the percentage of photons at each wavelength that contribute to the electric current of the cell can be measured by exposing the cell to a range of monochromatic light and then measuring the cell current. Dividing. the number of electrons output at each wavelength by the number of input photons at each wavelength gives the so-called quantum efficiency (QE). Note the generally high QE across the spectrum (left axis is percent) . However, there are observable losses, i.e., little or nothing is produced at wavelengths longer than about 850 nanometers. This is where the CdTe material becomes transparent (its band gap is about 1.5 eV, which corresponds to about an 825 nm wavelength). Similarly, there is not much sunlight with higher photon energy than about 3 eV, which corresponds to about 400 nm, so having a high QE in that area would not contribute current outdoors. The glass is also opaque at those short wavelengths and would block the sunlight.

Between about 400 and 850 nm, the glass in the related art cell of FIG. 4 reflects about 7% of the sunlight and absorbs another 7%. In contrast, the cell of the present invention would behave as in FIG. 5, by substituting low-iron glass (or highly transmissive borosilicate glass). About another 3% is absorbed unused in the commercial tin oxide bought with the glass in the related art cell of FIG. 4. In the present invention, substituted TCOs would have higher transmission and conduction.

The present invention also addresses the major loss between about 400 and about 500 nm. The CdS blocks light at its top surface in these wavelengths when it is too thick. The loss is equivalent to about 4 mA/cm², or 13% of the theoretical 30 mA/cm² current—a major loss. The present invention would regain most of this loss by thinning the CdS so it is nearly transparent and then adding a resistive buffer layer TCO of zinc tin oxide (ZTO) to protect the CdS/CdTe junction during manufacturing.

A careful examination of FIGS. 4 and 5 shows the desired 5 mA/cm2 improvement in current density:

From more transparent glass and TCOs: 2.9−0.7=2.2 mA/cm²

From thinner CdS protected by ZTO: 4.2−1.4=2.8 mA/cm².

An important benefit of the modules of the present invention resides in that they can be manufactured with high yield. That is, the modules of the present invention can reach the higher current density for modules without loss of overall efficiency or manufacturing yield. Just as much as the added efficiency, the added manufacturing yield at the higher performance is important to viability.

Scaling up a thin film cell, which is proven only at the laboratory level (about 1 cm²) , has been far from a simple matter. In fact, it has been a large block in progress for thin film PV over the last thirty years. Simple arithmetic shows it to be a factor of 10¹⁰ in scale-up from a proven 1 cm² technology to one capable of high-yield, commercial production at 100 MW per year output (10¹⁰ cm²) . This scale-up of sensitive, leading-edge semiconductor films and processes has been a serious barrier to commercial success in all thin film PV. It is not the same thing to have a small-area laboratory cell and to have a successful low-cost, large-area module product.

With that extra light obtained by the thin film PV modules of the present invention, the current densities would rise at least about 5 mA/cm² to about 25 mA/cm² or greater, and the efficiency would rise a similar ratio, 25%. This higher efficiency on a routinely fabricated commercial module is thus provided.

It is to be understood that the foregoing descriptions and specific embodiments shown herein are merely illustrative of the best mode of the invention and the principles thereof, and that modifications and additions may be easily made by those skilled in the art without departing for the spirit and scope of the invention, which is therefore understood to be limited only by the scope of the appended claims.

1-18. (canceled)

19. A CdTe-based photovoltaic module, comprising:
a conductive layer;
a zinc tin oxide buffer layer on the conductive layer; and
a cadmium sulfide layer having a thickness of about 0.1 μm or less on the buffer layer,
wherein the CdTe photovoltaic module has an active-area current density of about 23 mA/cm² or more.

20. The module as in claim 19, wherein the zinc tin oxide buffer layer has a composition with a stoichiometric ratio of ZnO/SnO₂ between about 0.25 and 3.

21. The module as in claim 19, wherein the zinc tin oxide buffer layer has a thickness between about 0.01 and about 0.5 μm.

22. A module as in claim 19, in wherein the cadmium sulfide layer includes oxygen up to about 25 atomic %.

23. The module as in claim 19, wherein the module has an area of about 120 cm×60 cm or larger.

24. The module as in claim 19, wherein the zinc tin oxide and the cadmium sulfide are deposited on float glass, including soda-lime glass or low-iron glass.

25. A method of manufacturing a CdTe photovoltaic module, comprising:
sputtering a zinc tin oxide buffer layer on a conductive TCO coating; and
sputtering a cadmium sulfide having a thickness of about 0.1 μm or less on the buffer layer,
wherein the photovoltaic module has an active-area current density of about 23 mA/cm² or more.

26. The method of claim 25, wherein the sputtering is RF or DC magnetron sputtering at ambient temperature.

27. The method as in claim 25, wherein the zinc tin oxide buffer layer has a composition with a stoichiometric ratio of ZnO/SnO₂ between about 0.25 and 3.

28. The method as in claim 25, wherein the zinc tin oxide buffer layer has a thickness between about 0.01 and about 0.5 μm.

29. The method as in claim 25, in wherein the cadmium sulfide layer includes oxygen up to 25 atomic %.

30. The method as in claim 25, wherein the ZTO and CdS are deposited on a float glass, including normal soda-lime glass or low-iron glass.

31. A CdTe-based photovoltaic module, comprising:
a low-iron glass superstrate;
a cadmium stannate conductive layer on the superstrate;
a zinc tin oxide buffer layer on the conductive layer; and
a cadmium sulfide layer having a thickness of about 0.1 μm or less on the buffer layer,
wherein the CdTe photovoltaic module has an active-area current density of about 25 mA/cm² or more.

32. The module as in claim 31, wherein the cadmium stannate conductive layer is about 0.1-0.5 μm thick.

33. The module as in claim 31, wherein the zinc tin oxide buffer layer has a composition with a stoichiometric ratio of ZnO/SnO₂ between about 0.25 and 3.

34. The module as in claim 31, wherein the zinc tin oxide buffer layer has a thickness between about 0.01 and about 0.5 μm.

35. The module as in claim 31, in wherein the cadmium sulfide layer includes oxygen up to about 25 atomic %.

36. The module as in claim 31, wherein the cadmium stannate layer, the zinc tin oxide layer, and the cadmium sulfide layer are sputtered layers.

37. The module as in claim 31, wherein the low iron glass is low iron float glass containing less than about 0.15% by weight of Fe.

38. The module as in claim 31, wherein the cadmium stannate layer has a thickness of about 0.3 μm.

39. The module as in claim 31, wherein the low iron glass has a transmissiveness of about 0.9 or greater in a spectrum of interest (about 300 to 900 nm wavelength).

40. The module as in claim 31, wherein the module has an area of about 120 cm×60 cm or larger.

41. A method of manufacturing a CdTe photovoltaic module comprising:
providing a low-iron glass superstrate;
sputtering a cadmium stannate conductive coating on the superstrate;
sputtering a zinc tin oxide buffer layer on the conductive coating; and
sputtering a cadmium sulfide having a thickness of about 0.1 μm or less on the buffer layer,
wherein the photovoltaic module has an active-area current density of about 25 mA/cm² or more.

42. The method of claim 41, wherein the sputtering is RF or DC magnetron sputtering at ambient temperature.

43. The method as in claim 41, wherein the cadmium stannate conductive layer is about 0.1-0.5 μm thick.

44. The method as in claim 41, wherein the zinc tin oxide buffer layer has a composition with a stoichiometric ratio of ZnO/SnO₂ between about 0.25 and 3.

45. The method as in claim 41, wherein the zinc tin oxide buffer layer has a thickness between about 0.01 and about 0.5 μm.

46. The method as in claim 41, in wherein the cadmium sulfide layer includes oxygen up to 25 atomic %.

47. The method as in claim 41, wherein the low iron glass is low iron float glass containing less than about 0.15% by weight of Fe.

48. The method as in claim 41, wherein the low iron glass has a transmissiveness of about 0.9 or greater in a spectrum of interest (about 300 to 900 nm wavelength).
